(19) United States
(12) Patent Application Publication
(10) Pub. No.: US 2023/0413463 A1
(43) Pub. Date: Dec. 21, 2023

(54) INTEGRAL ENCLOSURE INTEGRATION SYSTEM

(71) Applicant: ARRIS ENTERPRISES LLC, Suwanee, GA (US)

(72) Inventor: Arun Kumar PADERA, Bangalore (IN)

(21) Appl. No.: 18/038,254

(22) PCT Filed: Oct. 21, 2021
(86) PCT No.: PCT/US21/55952

§ 371 Date: May 23, 2023

Related U.S. Application Data
(60) Provisional application No. 63/118,236, filed on Nov. 25, 2020.

(51) Int. Cl. H05K 5/02; H05K 5/00; H01R 33/97; G11B 33/12

(52) U.S. Cl. CPC H05K 5/0221; H05K 5/0021; H05K 5/0247; H01R 33/97; G11B 33/126; G11B 33/128; H01R 2201/06; H01R 33/945

(57) ABSTRACT

An integral system providing for the coupling of multiple component enclosures, such as those containing information appliances and information storage media and systems. The system utilizes one or more couplers integrated into one of the enclosures and adapted to mate with coupler receptacles upon another enclosure. The couplers include latch and knob components, wherein the knob is actuated to engage and disengage the enclosure coupling. In addition, the couplers are configured so that users can readily actuate the knob component when the enclosures are in a coupled or uncoupled state. The disclosed technology also provides for the establishment of a data and/or power connection to be established between enclosures as a consequence of the aforementioned coupling.

### BACKGROUND OF THE INVENTION

As more and more information appliances (media gateways, set-top boxes, routers, modems, etc.) are integrated into residential environments, it has become increasingly necessary to ensure that such residential equipment can be installed, upgraded and maintained by average consumers. Service providers, typically the owners of these residential media appliances, desire this consumer-friendly quality to help ensure a positive customer experience and to avoid the expense of dispatching technicians to a customer location. Consumers appreciate equipment that can be installed on their schedule, without a service appointment.

One of the most ubiquitous types of residential information appliances in use today is the set-top box. These appliances typically serve as the primary nexus and interface for the provision of broadband media services and content delivered by cable, optical or satellite systems. It is not unusual for these appliances to include digital video recording (“DVR”) functionality which enables consumers to record and store media content locally. This media storage is typically supported by a hard-disk drive (“HDD”) or solid-state drive (“SSD”) associated with the information appliance. While a portion of this storage may be internal to the media appliance, consumers often supplement the storage with external memory (either HDD or SDD). Such external memory usually requires a connection to a dedicated external power supply and is most often linked to the media appliance by a universal serial bus (“USB”) or serial AT attachment (“SATA”) cable.

While numerous types of HDD and SSD memory options are available to consumers, it would be advantageous for both the service provider and the consumer to have a simple means of installing and integrating additional, compatible external memory into a residential media appliance environment. Ideally the mating of this external memory with the existing information appliance would require little or no connecting cables, external power supplies, or specialized tools or knowledge.

### BRIEF SUMMARY OF THE INVENTION

An integral system providing for the coupling of multiple component enclosures, such as those containing information appliances and information storage media and systems. The system utilizes one or more couplers integrated into one of the enclosures and adapted to mate with coupler receptacles upon another enclosure. The couplers include latch and knob components, wherein the knob is actuated to engage and disengage the enclosure coupling. In addition, the couplers are configured so that users can readily actuate the knob component when the enclosures are in a coupled or uncoupled state. The disclosed technology also provides for the establishment of a data and/or power connection to be established between enclosures as a consequence of the aforementioned coupling.

### BRIEF DESCRIPTION OF THE DRAWINGS

The aspects, and advantages of the present invention will become better understood with regard to the following description, appended claims, and accompanying drawings in which:

FIG. 1 is a top, front and bottom view of an HDD/SDD enclosure in accordance with a particular embodiment of an integral enclosure integration system.

FIG. 2A is a cross-sectional sideview of the enclosure of FIG. 1.

FIG. 2B is a side perspective view of a connector in accordance with the embodiment of FIG. 1.

FIG. 3 is a top, front and bottom view of an information appliance enclosure in accordance with a particular embodiment of an integral enclosure integration system.

FIG. 4A is a side perspective view of a connector and a connector receptacle in accordance with the embodiments of FIGS. 1 and 3.

FIG. 4B is a side perspective view of a connector engaged with a connector receptacle in accordance with the embodiments of FIGS. 1 and 3.

FIG. 5 is a front view of the HDD/SDD enclosure of FIG. 1 coupled to the information appliance enclosure of FIG. 3.

FIG. 6A is planar view of a connector receptacle in accordance with the information appliance enclosure of FIG. 3.

FIG. 6B is planar view of a latch engaged with the connector receptacle of FIG. 6A.

FIG. 7 is a partial cross-section perspective view of the HDD/SDD enclosure of FIG. 1 coupled to the information appliance enclosure of FIG. 3.

### DETAILED DESCRIPTION

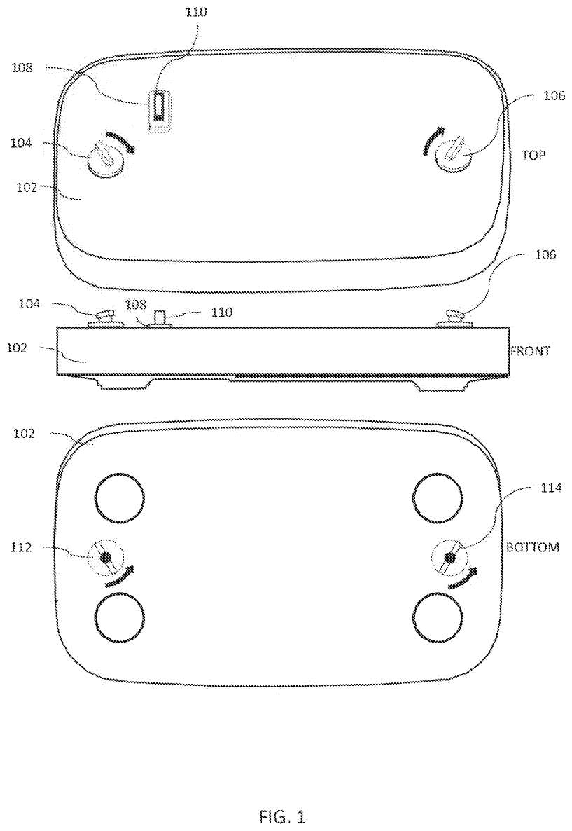

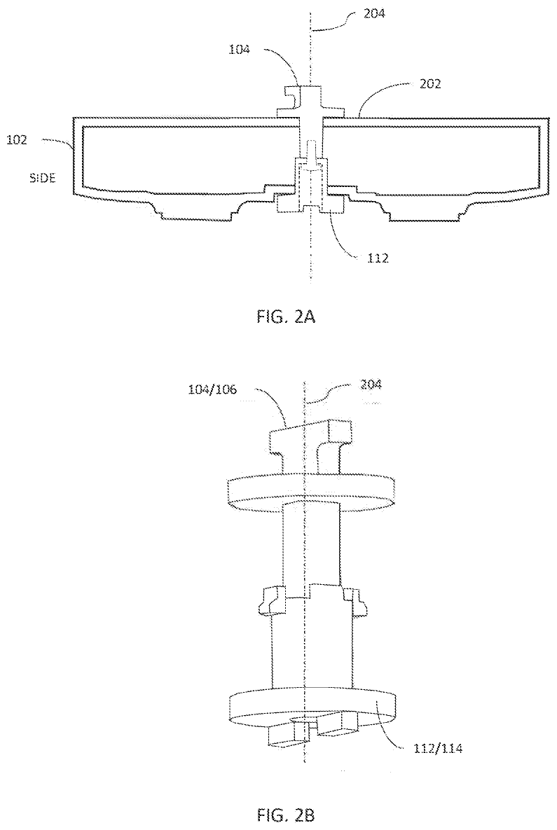

FIG. 1 provides a top, front and bottom view of HDD/SDD enclosure 102. As shown, enclosure 102 includes two latches (104, 106) extending from the top surface. The top surface also includes a rectangular opening (108) through which electrical connecter 110 extends. This connector would ideally include both data and power connections for the HDD/SDD memory contained within enclosure 102. The bottom view of HDD/SDD enclosure 102 shows two circular knobs, 112 and 114, each affixed to one of the latches (104 and 106, respectively). Each latch has a substantially T-shaped cross-section. FIG. 2A provides a cross-sectional sideview of enclosure 102 and shows how knob 112 is secured to latch 104 by internal screw (202). Knob 114 is similarly attached to latch 106. Also, as shown in FIG. 2A, the connector formed by the union of knob 112 and latch 104 is positioned within a cylindrical void in HDD/SDD enclosure 102.

FIG. 2B provides a more detailed depiction of connector comprised of a knob (112/144) and a latch (104/106). The knob and latch are each fabricated from a plastic, such as acrylonitrile butadiene styrene (“ABS”), or any similar material that may be readily fabricated and/or machined into the desired shape and configuration. Constructing each connector from two components (knob and latch) permits the connector to be assembled after each of these components is inserted into a cylindrical void in the HDD/SDD enclosure (the latch from the top and the knob from the bottom). Once the two components are joined to each other with an internal screw, the connector is effectively secured to the HDD/SDD enclosure in a manner that permits the connector to be rotated about the primary axis of the cylindrical void (see dashed line 204 in FIGS. 2A and 2B). As mentioned above, each knob is secured to each latch by an internal screw. This connection, secures interlocking surfaces on each knob and latch together, and thereby ensures that application of a sufficient rotational torque to a knob will result in the latch being rotated similarly rotated (see arrow indicators in FIG. 1).

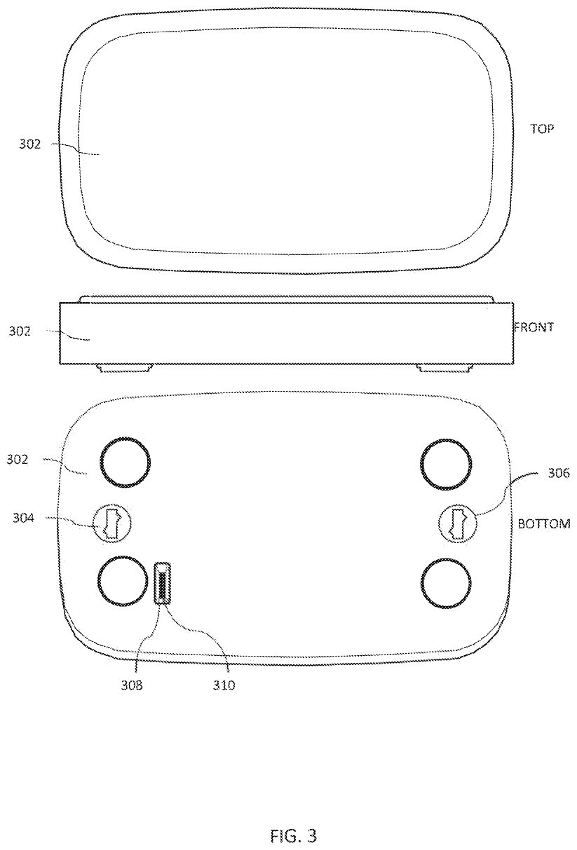

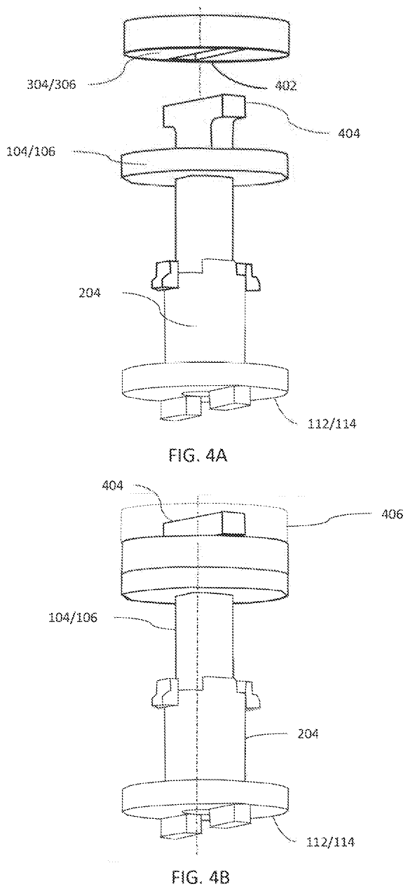

FIG. 3 provides a top, front and bottom view of an information appliance enclosure 302. This enclosure is adapted to house the electronics and connectors supporting set-top box, modem, or other information appliance functionality. The bottom view of enclosure 302 shows two latch receptacles, 304 and 306, each positioned to align with the latches located on the top of HDD/SDD enclosure 102. Each receptacle has a substantially rectangular opening adapted to accept a top portion of a latch (104, 106), and void into which the top of a latch, when the latch is aligned with the substantially rectangular opening, can be inserted. FIG. 4A provides a detailed view of a connector, comprised of a latch (104/106) joined to a knob (112/114), positioned so as to be in substantial alignment with the rectangular opening (402) of a latch receptacle (304/306). The bottom of enclosure 302 also includes rectangular opening 308, which permits access to electrical receptacle 310. This receptacle is adapted to mate with electrical connector 110.

When information appliance enclosure 302 is appropriately positioned above HDD/SDD enclosure 102, and latches 104 and 106 are properly aligned with the substantially rectangular openings of latch receptacles 112 and 114, the two enclosures can be brought into contact with another. This will result in the insertion of the top of the T-shaped latches into the substantially rectangular opening of the latch receptacles. Each of the T-shaped latches is configured so that its widest portion (404) clears structure of each receptacle that defines the substantially rectangular opening, and enters a void within the body of information appliance enclosure 302 (represented in FIG. 4B by the cylindrical volume outlined by dotted line 404).

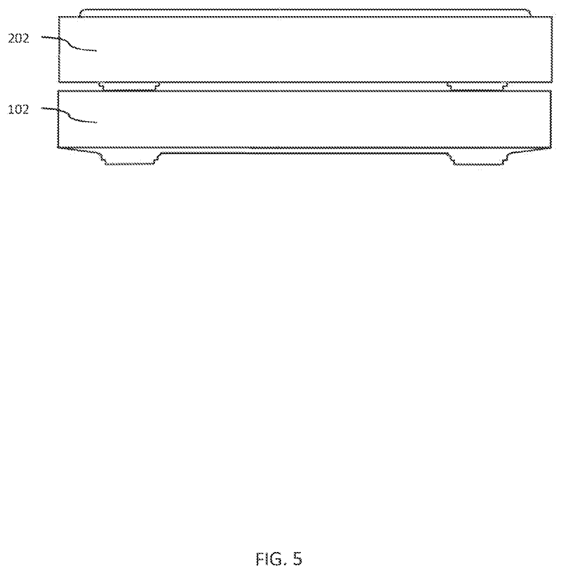

This alignment/insertion permits the bottom of information appliance enclosure 302 to be brought into direct contact with the top of HDD/SDD enclosure 102 (see FIG. 5). This also results in electrical connecter 110 (which extends from the top of SDD/HDD enclosure 102) mating with electrical receptacle 310. This mating enables power to be supplied to the HDD/SDD memory from the information appliance, and enables bidirectional data transmission between the enclosures. With the tops of the latches (104, 106) fully inserted into the rectangular openings of the latch receptacles (304, 306), each of the knobs (112, 114) is rotated. This rotation causes the widest portion of the T-shaped latches to rotate within the void above each the rectangular opening, and thereby take the widest portion of each latch out of alignment with each of the substantially rectangular openings.

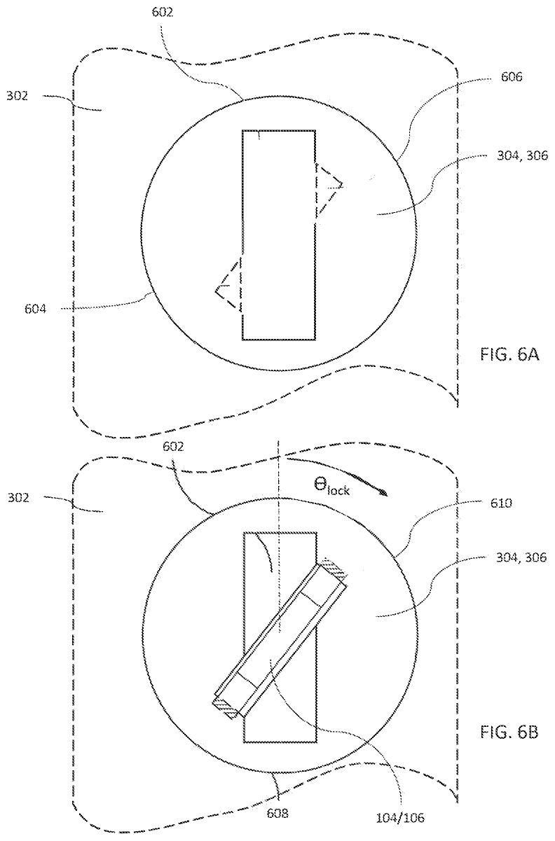

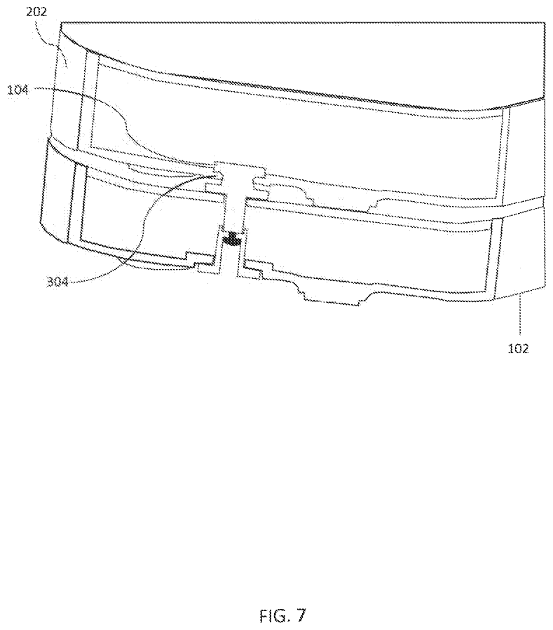

A detail of a latch receptacle (304/306) is shown in FIG. 6A. Note that each of the substantially rectangular openings (602) is supplemented by two triangular cut-outs (604, 606). These cut-outs permit the T-latch (104/106) to be rotated Block degrees. This rotation causes widest portion (404) of the T-shaped latch (104, 106) to overlap and engage with the material comprising the latch receptacle (304/306). This overlapping and engagement is illustrated in FIG. 6B. The overlapping portion of the T-shaped latch is represented by the dotted line regions 608 and 610. FIG. 7 provides a partial cutaway view of the coupled enclosures (102 and 204), showing latch 104 engaged with the inner surface of latch receptacle 304.

Although the invention herein has been described with reference to particular embodiments, it is to be understood that these embodiments are merely illustrative of the principles and applications of the present invention. For example, different means of joining the latch and knob components could be employed (rivets, glue, friction, etc.). In addition, the particular shape of the latches (T-shaped) and latches receptacles (substantially rectangular) could be varied without departing from the scope of the disclosed technology. The primary constraint being that the latches remain geometrically compatible with the receptacles, and a sufficient degree of latch rotation is afforded to achieve an effective coupling between the enclosures. The electrical connection between the enclosures enabled by this technology could also be achieved via other means, such as inductive coupling, the primary constraint being the alignment of the inductive coupling region of one enclosure with that of the other. Furthermore, various materials commonly used in the manufacture of connectors and enclosures could be utilized to fabricate any of the components that have been disclosed. It should also be understood that although the particular embodiments disclosed above described the latches as being associated with the HDD/SDD enclosure, and the latch receptacles as being associated with the information appliance enclosure, they could be utilized on either or both of the enclosure types. Nor is this disclosure limited to HDD/SDD and/or information appliance enclosures, nor is it limited to two enclosures. The system is readily adaptable for the coupling of any number of enclosures in a stacked arrangement, and these enclosures could contain any number of active or passive systems and/or components. All of the above variations and reasonable extensions therefrom could be implemented and practiced without departing from the spirit and scope of the present invention as defined by the appended claims.

1. A system for coupling component enclosures, comprising:
a first enclosure having at least a first surface and comprising at least one connector receptacle positioned upon the first surface;
a second enclosure having at least a first surface configured to be brought into proximity with the first surface of the first enclosure;
at least one connector comprising an actuator and a latch, wherein:
the latch is positioned on the first surface of the second enclosure and adapted to mate with the connector receptacle;
the actuator is mechanically linked to the actuator so as to function to engage and disengage the latch with the connector receptacle; and
the actuator is accessible from a second surface of the second enclosure when the first surface of the first enclosure is in proximity with the first surface of the second enclosure.

2. The system of claim 1 wherein;
the second enclosure further comprises at least one cylindrical void positioned between the first and second surfaces of the second enclosure; and
the actuator is linked to the latch via the at least one cylindrical void.

3. The system of claim 1 wherein the actuator comprises a knob.

4. The system of claim 1 wherein the actuator is further adapted to rotate the latch when actuated.

5. The system of claim 1 wherein the first enclosure comprises at least one of the following:
an information appliance;
a set-top box;
a router;
a media gateway;
a power source; and
a modem.

6. The system of claim 1 wherein the second enclosure comprises at least one of the following:
a hard-disk drive;
a solid-state memory drive;
an information storage device; and
a device requiring an external power source.

7. The system of claim 1 wherein the latch comprises a substantially T-shaped cross-sectional profile.

8. The system of claim 7 wherein the at least one connector receptacle comprises a substantially rectangular opening in the first surface of the first enclosure.

9. The system of claim 8 further comprising a void accessible via the substantially rectangular opening, wherein the void is dimensioned so as to permit rotation of the latch within it when upon the first surface of the first enclosure is brought into proximity with the first surface of the second enclosure.

10. The system of claim 1 further comprising:
at least one electrical coupler positioned upon the first surface of the first enclosure; and
at one second electrical coupler positioned upon the first surface of the second enclosure;
and wherein:
at least one connection is established between the first electrical coupler and the second electrical coupler upon the first surface of the first enclosure is brought into proximity with the first surface of the second enclosure.

11. The system of claim 10 wherein at least one connection comprises at least one of the following:
a data connection;
a power connection; and
an inductive link.
